(19) United States
(12) Patent Application Publication
(10) Pub. No.: US 2006/0266991 A1
(43) Pub. Date: Nov. 30, 2006

(54) Phase change memory device and method for manufacturing the same

(76) Inventors: Heon Yong Chang, Kyoungki-do (KR); Suk Kyoung Hong, Kyoungki-do (KR); Hae Chan Park, Seoul (KR)

Correspondence Address: LADAS & PARRY LLP, 224 SOUTH MICHIGAN AVENUE, SUITE 1600, CHICAGO, IL, 60604, US

(21) Appl. No.: 11/247,318

(22) Filed: Oct. 11, 2005

(30) Foreign Application Priority Data
May 26, 2005 (KR) 10-2005-0044604

(51) Int. Cl. H01L 47/00

(52) U.S. Cl. 257/4

(57) ABSTRACT

Disclosed is a phase change memory device having a uniformly decreased writing current necessary for phase change of a phase change layer and a method for manufacturing the same. The phase change memory device includes a semiconductor substrate having a lower pattern; a first oxide layer formed on the semiconductor substrate to cover the lower pattern; a bottom electrode contact formed as a plug shape within the first oxide layer; a nano-size insulation layer formed on the first oxide layer including the bottom electrode contact; a phase change layer formed on the nano-size insulation layer; a top electrode formed on the phase change layer; a second oxide layer formed on the overall surface of the resulting substrate to cover a phase change cell having the bottom electrode contact, the nano-size insulation layer, the phase change layer, and the top electrode laminated successively; and a metal wiring formed within the second oxide layer to contact the top electrode. The nano-size insulation layer is made of any one chosen from a group including silicon oxide (SiO₂), aluminum oxide (Al₂O₃), hafnium oxide (HfO₂), and zirconium oxide (ZrO₂) or from a group including silicon nitride (SiN) and aluminum nitride (AlN).

### BACKGROUND OF THE INVENTION

1. Field of the Invention

The present invention relates to a phase change memory device and a method for manufacturing the same, and more particularly to a phase change memory device having a uniformly decreased writing current necessary for phase change of a phase change layer and a method for manufacturing the same.

2. Description of the Prior Art

As generally known in the art, memory devices are classified into volatile RAM (random access memory) devices, which lose inputted information when power supply is interrupted, and nonvolatile ROM (read only memory) devices, which retain inputted information even when power supply is interrupted. The volatile RAM devices include DRAMs and SRAMs. The nonvolatile ROM devices include flash memories such as EEPROMs (electrically erasable and programmable ROMs).

However, the DRAMs are difficult to highly integrate, because they must have high charge-storage ability and the surface area of electrodes must be increased accordingly, although they are very excellent memory devices as widely known in the industry.

The flash memories are also difficult to highly integrate, because they need an operating voltage higher than the power supply voltage, regarding their structure of having two integrated gates, and a separate booster circuit to build up a voltage necessary for writing and deleting operations.

Therefore, much research has been performed to develop a new memory device which has a simple structure and can be highly integrated while having the properties of nonvolatile memory devices. For example, a phase change memory device has been proposed recently.

The phase change memory device reads out information stored on a cell by means of the difference in resistance between crystalline and amorphous states, when electric currents flow between top and bottom electrodes and a phase change layer interposed between them undergoes phase change from a crystalline state to an amorphous state.

More particularly, the phase change memory device has a phase change layer made of chalcogenide, which is a compound including germanium (Ge), stibium (Sb), and tellurium (Te) and undergoes phase change between amorphous and crystalline states by means of current application (i.e., joule heat). Based on the fact that specific resistance of the phase change layer in the amorphous state is higher than that in the crystalline state, the phase change memory device senses the current flowing through the phase change layer in writing and reading modes and determines whether the information stored in the phase change memory cell corresponds to logic ‘1’ or logic ‘0’.

In the phase change memory device, at least 1 mA of current must flow so that the phase change layer can undergo phase change. Therefore, the contact area between the phase change layer and the electrodes must be reduced to decrease the current necessary for phase change of the phase change layer.

A conventional phase change memory device will now be described with reference to FIG. 1, which is a sectional view thereof.

As shown, gates 4 are formed in the active region of a semiconductor substrate 1, which is delimited by a device isolation layer, and bond regions (not shown) are formed on both sides of the gates 4 within the substrate surface.

An insulation interlayer 5 is formed on the overall surface of the substrate to cover the gates 4. First and second tungsten plugs 6a and 6b are formed within parts of the insulation interlayer corresponding to a region, in which a phase change cell is to be formed, and another region, to which a ground voltage Vss is to be applied, respectively.

A first oxide layer 7 is formed on the insulation interlayer 5 including the first and second tungsten plugs 6a and 6b. Although not shown in detail, a metal pad 8 is formed as a dot in the region in which a phase change cell is to be formed in a Damascene process to contact the first tungsten plug 6a. In addition, a ground line 9 is formed as a bar in the region to which a ground voltage is to be applied to contact the second tungsten plug 6b.

A second oxide layer 10 is formed on the first oxide layer 7 including the metal pad 8 and the ground line 9. A bottom electrode contact 11 is formed as a plug shape within the second oxide layer 10 in the region in which a phase change cell is to be formed to contact the metal pad 8.

A phase change layer 12 and a top electrode 13 are laminated as patterns on a part of the second oxide layer, on which a phase change cell is to be formed, to contact the bottom electrode contact 11. The plug-type bottom electrode, particularly, the bottom electrode contact 11, and the phase change layer 12 and top electrode 13 laminated thereon constitute a phase change cell.

A third oxide layer 14 is formed on the second oxide layer 10 to cover the phase change cell. A top electrode contact 15 is formed as a plug shape within the third oxide layer 14 to contact the top electrode 13. A metal wiring 15 is formed on the third oxide layer 14 to contact the top electrode contact 15.

However, conventional phase change memory devices have problems as follows:

In the case of phase change memory devices, as mentioned above, it is required to reduce the contact area between the electrode and the phase change layer, particularly between the bottom electrode contact and the phase change layer, for stable phase change of the phase change layer. To this end, the bottom electrode contact must have a small size and, according to the prior art, is formed in an E-beam (electron-beam) exposure process, which has higher resolution than an ArF exposure process.

When the bottom electrode contact is formed in an E-beam exposure process, however, it cannot be formed with a uniform size throughout the entire region of the substrate. As a result, the contact area between the bottom electrode contact and the phase change layer varies depending on the position on the substrate. Consequently, the writing current range increases and it becomes impossible to secure stable electrical properties of the phase change memory devices.

### SUMMARY OF THE INVENTION

Accordingly, the present invention has been made to solve the above-mentioned problems occurring in the prior art, and an object of the present invention is to provide a phase change memory device having a uniformly decreased writing current necessary for phase change of a phase change layer and a method for manufacturing the same.

Another object of the present invention is to provide a phase change memory device having a uniformly decreased writing current necessary for phase change of a phase change layer to secure stable electrical properties and a method for manufacturing the same.

In order to accomplish these objects, there is provided a phase change memory device including a semiconductor substrate having a lower pattern; a first oxide layer formed on the semiconductor substrate to cover the lower pattern; a bottom electrode contact formed as a plug shape within the first oxide layer; a nano-size insulation layer formed on the first oxide layer including the bottom electrode contact; a phase change layer formed on the nano-size insulation layer; a top electrode formed on the phase change layer; a second oxide layer formed on the overall surface of the resulting substrate to cover a phase change cell having the bottom electrode contact, the nano-size insulation layer, the phase change layer, and the top electrode laminated successively; and a metal wiring formed within the second oxide layer to contact the top electrode.

The nano-size insulation layer has a thickness of 1-9 nm.

The nano-size insulation layer is made of any one chosen from a group including silicon oxide (SiO₂), aluminum oxide (Al₂O₃), hafnium oxide (HfO₂), and zirconium oxide (ZrO₂).

The nano-size insulation layer is made of silicon nitride (SiN) or aluminum nitride (AlN).

The phase change memory device further includes a bottom electrode interposed between the first oxide layer, including the bottom electrode contact, and the nano-size insulation layer.

The metal wiring has a top electrode contact formed as a plug shape within the second oxide layer to contact the top electrode. The metal wiring and the top electrode contact are integral with each other.

According to another aspect of the present invention, there is provided a method for manufacturing a phase change memory device including the steps of providing a semiconductor substrate having a lower pattern; forming a first oxide layer on the overall surface of the substrate to cover the lower pattern; forming a bottom electrode contact as a plug shape within the first oxide layer; forming a nano-size insulation layer on the first oxide layer including the bottom electrode contact; forming a phase change layer and a top electrode successively on the nano-size insulation layer; forming a second oxide layer on the overall surface of the resulting substrate to cover a phase change cell having the bottom electrode contact, the nano-size insulation layer, the phase change layer, and the top electrode laminated successively; etching the second oxide layer to form a contact hole which exposes the top electrode; depositing a metal layer on the second oxide layer to fill the contact hole; and patterning the metal layer to form a top electrode contact within the second oxide layer to contact the top electrode and a metal wiring on the second oxide layer to contact the top electrode contact.

The method for manufacturing a phase change memory device further includes a step of forming a bottom electrode on the first oxide layer including the bottom electrode contact, after the step of forming a bottom electrode contact and before the step of forming a nano-size insulation layer.

### BRIEF DESCRIPTION OF THE DRAWINGS

The above and other objects, features and advantages of the present invention will be more apparent from the following detailed description taken in conjunction with the accompanying drawings, in which:

FIG. 1 is a sectional view showing a conventional phase change memory device;

FIGS. 2A to 2E are sectional views showing the respective processes of a method for manufacturing a phase change memory device according to an embodiment of the present invention; and

FIG. 3 is a sectional view showing a phase change memory device according to another embodiment of the present invention.

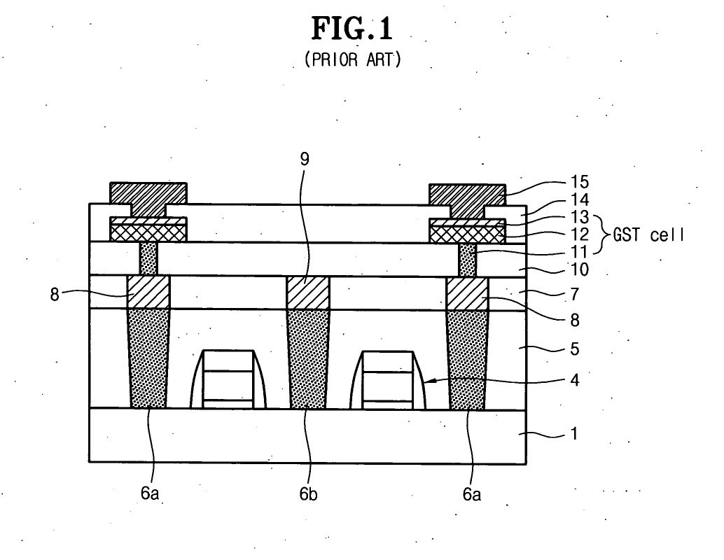

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

The technological principle of the present invention will now be described.

According to the present invention, a nano-size insulation layer is formed on the bottom electrode contact with a thickness of nm order. A phase change layer and a top electrode are then formed on the nano-size insulation layer. The nano-size insulation layer acts as a heater, not an insulator, and increases the current density. As a result, the writing current necessary for phase change of the phase change layer decreases.

As such, the present invention uses a method of interposing a nano-size insulation layer between the bottom electrode contact and the phase change layer, not a method of reducing the contact area between them, to decrease the writing current necessary for phase change of the phase change layer. Therefore, uniformity can be secured, in contrast to the prior art, and the electrical properties of the phase change memory device can be improved.

As the phase change layer undergoes phase change between crystalline and amorphous states, the interface between the bottom electrode contact and the phase change layer varies its volume and the interface properties degrade. If writing and reading operations are repeated to the phase change memory device, the phase change layer does not undergo phase change from the crystalline state to the amorphous state any longer, due to degraded interface properties, and is stuck in the crystalline state. However, since a nano-size insulation layer is interposed between the bottom electrode contact and the phase change layer according to the present invention, degradation of properties of the interface between the bottom electrode contact and the phase change layer is avoided and the phase change layer is prevented from stuck in the crystalline state. Consequently, degradation of properties caused by the programming cycle which repeats writing and reading operations is avoided.

In addition, the present invention does not reduce the size of the bottom electrode contact for decreased writing current and the bottom electrode contact can be formed in a KrF or ArF process, not in an E-beam process. As a result, the process development cost can be reduced than when using a conventional exposure process.

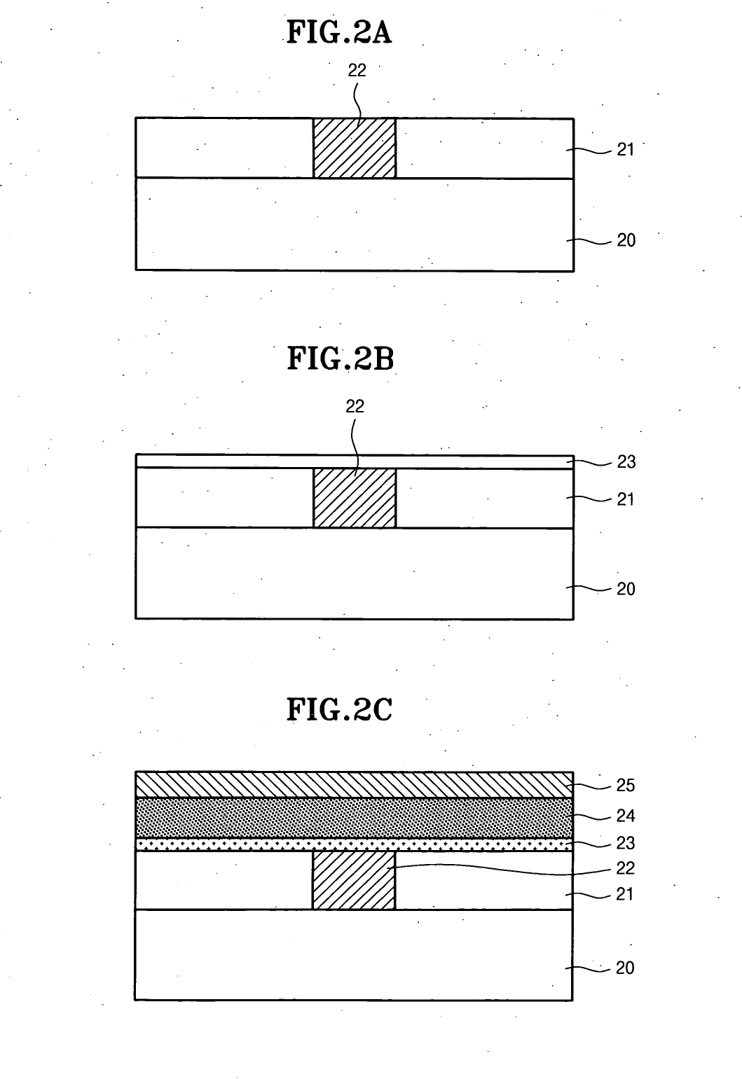

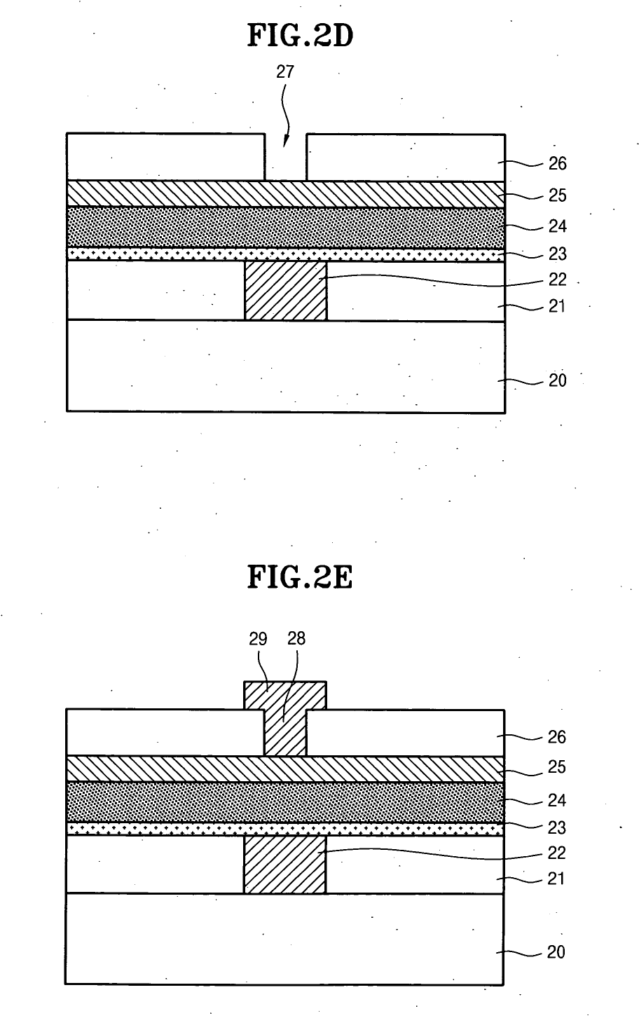

A method for manufacturing a phase change memory device according to an embodiment of the present invention will now be described in detail with reference to FIGS. 2A to 2E, which are sectional views showing the respective processes thereof.

Referring to FIG. 2A, a first oxide layer 21 is formed on a semiconductor substrate 20, which has a lower pattern formed thereon (not shown), to cover the lower pattern. The first oxide layer 21 is etched to form a contact hole for exposing the lower pattern or the substrate 20. A conductive layer, such as a silicon layer or a metal layer, is embedded in the contact hole to form a bottom electrode contact 22 as a plug shape. Preferably, the contact hole is formed in a KrF or ArF process, which has gone through process development, instead of an E-beam exposure process.

Referring to FIG. 2B, a nano-size insulation layer 23 is formed on the first oxide layer 21 including the bottom electrode contact 22 with a thickness of 1-9 nm. The nano-size insulation layer 23 is made of an oxide, such as silicon oxide (SiO₂), aluminum oxide (Al₂O₃), hafnium oxide (HfO₂), or zirconium oxide (ZrO₂), or a nitride such as silicon nitride (SiN) or aluminum nitride (AlN).

As generally know in the art, if an insulation layer has a thickness of more than 100 Å, it acts as an insulator. Therefore, the nano-size insulation layer 23 according to the present invention has a thickness of less than 100 Å (i.e., nanometer order) so that it acts as a heater, not an insulator.

Referring to FIG. 2C, a phase change layer 24 and a top electrode 25 are successively formed on the nano-size insulation layer 23 and are patterned to provide a phase change cell, which has the bottom electrode contact 22, the nano-size insulation layer 23, the phase change layer 24, and the top electrode 25 laminated one by one.

Referring to FIG. 2D, a second oxide layer 26 is formed on the overall surface of the resulting substrate, which has a phase change cell formed thereon, and is subjected to an etch-back or CMP process to make its surface planar. The second oxide layer 26 is then etched in a conventional process to form a contact hole 27 which exposes the top electrode 25.

Referring to FIG. 2E, a metal layer is deposited on the second oxide layer 26 to fill the contact hole 27. The metal layer is patterned in a conventional process to form a top electrode contact 28 in the contact hole 27, which contacts the top electrode 25, and a metal wiring 29 on the second oxide layer 26. The top electrode contact 28 and the metal wiring 29 are preferably integral with each other.

Subsequently, a series of conventional processes are performed to complete the phase change memory device according to the present invention.

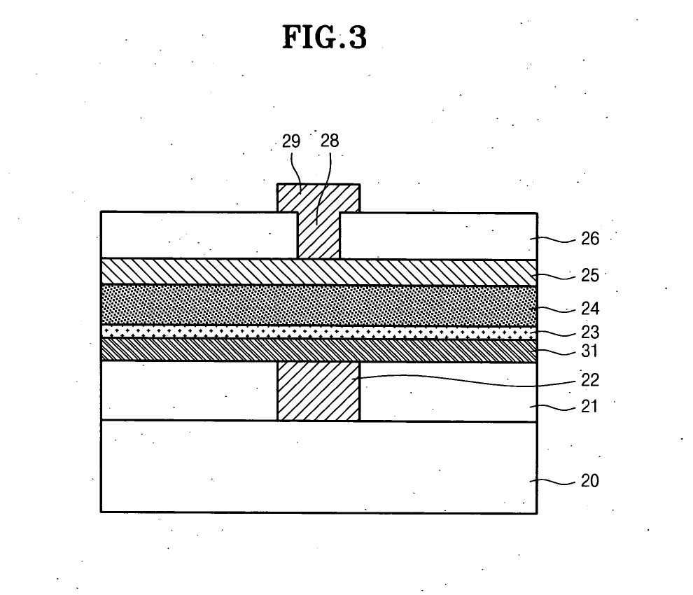

In the present invention, the nano-size insulation layer is formed on the first oxide layer including the bottom electrode contact. In an alternative embodiment as shown in FIG. 3, a bottom electrode 31 is formed on the first oxide layer including the bottom electrode contact and a nano-size insulation layer 23 and a phase change layer 24 are successively formed on the bottom electrode 31.

As the nano-size insulation layer 23 is formed on the bottom electrode 31 in this manner, the current path becomes smaller and self-heating is realized. Therefore, the phase change memory device according to this embodiment has a contact area than that of the previous embodiment and is less influenced by change of volume. This reduces the current necessary for phase change of the phase change layer.

As mentioned above, the phase change memory device according to the present invention has a nano-size insulation layer formed on the bottom electrode contact to act as a heater, when a current path is established from the bottom electrode contact to the top electrode, and increase the serial resistance between the bottom electrode contact and the phase change layer. This effectively reduces the current necessary for phase change of the phase change layer.

In addition, the present invention can adjust the current density by regulating the thickness of the nano-size insulation layer 24 and can secure uniformity more easily than the conventional method of controlling the current density by regulating the size of the bottom electrode contact, which affects the contact area between the bottom electrode contact and the phase change layer.

AS the writing current decreases, transistors can have a smaller size. This reduces the cell size and improves the cell efficiency.

According to the prior art, phase change of the phase change layer occurs on the very small interface with the bottom electrode contact and volume change occurs during phase change of the phase change layer. As a result, the phase change layer is often stuck in the crystalline state. However, according to the present invention, the contact area between the bottom electrode contact and the phase change layer is not small and the phase change layer is prevented from being stuck. This results in remarkable improvements depending on the number of programming cycle.

Since the invention does not reduce the size of the bottom electrode contact to decrease the current necessary for phase change of the phase change layer, the bottom electrode contact can be formed in a KrF or ArF process, not an E-beam process. This reduces the process development cost.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A phase change memory device comprising:
a semiconductor substrate having a lower pattern;
a first oxide layer formed on the semiconductor substrate to cover the lower pattern;
a bottom electrode contact formed as a plug shape within the first oxide layer;
a nano-size insulation layer formed on the first oxide layer including the bottom electrode contact;
a phase change layer formed on the nano-size insulation layer;
a top electrode formed on the phase change layer;
a second oxide layer formed on the overall surface of the resulting substrate to cover a phase change cell having the bottom electrode contact, the nano-size insulation layer, the phase change layer, and the top electrode laminated successively; and
a metal wiring formed within the second oxide layer to contact the top electrode.

2. The phase change memory device as claimed in claim 1, wherein the nano-size insulation layer has a thickness of 1-9 nm.

3. The phase change memory device as claimed in claim 1, wherein the nano-size insulation layer is made of any one chosen from a group comprising silicon oxide (SiO₂), aluminum oxide (Al₂O₃), hafnium oxide (HfO₂), and zirconium oxide (ZrO₂).

4. The phase change memory device as claimed in claim 1, wherein the nano-size insulation layer is made of silicon nitride (SiN) or aluminum nitride (AlN).

5. The phase change memory device as claimed in claim 1, further comprising a bottom electrode interposed between the first oxide layer, including the bottom electrode contact, and the nano-size insulation layer.

6. The phase change memory device as claimed in claim 1, wherein the metal wiring has a top electrode contact formed as a plug shape within the second oxide layer to contact the top electrode.

7. The phase change memory device as claimed in claim 6, wherein the metal wiring and the top electrode contact are integral with each other.

8. A method for manufacturing a phase change memory device comprising the steps of:
providing a semiconductor substrate having a lower pattern;
forming a first oxide layer on the overall surface of the substrate to cover the lower pattern;
forming a bottom electrode contact as a plug shape within the first oxide layer;
forming a nano-size insulation layer on the first oxide layer including the bottom electrode contact;
forming a phase change layer and a top electrode successively on the nano-size insulation layer;
forming a second oxide layer on the overall surface of the resulting substrate to cover a phase change cell having the bottom electrode contact, the nano-size insulation layer, the phase change layer, and the top electrode laminated successively;
etching the second oxide layer to form a contact hole which exposes the top electrode;
depositing a metal layer on the second oxide layer to fill the contact hole; and
patterning the metal layer to form a top electrode contact within the second oxide layer to contact the top electrode and a metal wiring on the second oxide layer to contact the top electrode contact.

9. The method for manufacturing a phase change memory device as claimed in claim 8, wherein the nano-size insulation layer has a thickness of 10-99 nm.

10. The method for manufacturing a phase change memory device as claimed in claim 8, wherein the nano-size insulation layer is made of any one chosen from a group comprising silicon oxide (SiO₂), aluminum oxide (Al₂O₃), hafnium oxide (HfO₂), and zirconium oxide (ZrO₂).

11. The method for manufacturing a phase change memory device as claimed in claim 8, wherein the nano-size insulation layer is made of silicon nitride (SiN) or aluminum nitride (AlN).

12. The method for manufacturing a phase change memory device as claimed in claim 8, further comprising a step of forming a bottom electrode on the first oxide layer including the bottom electrode contact, after the step of forming a bottom electrode contact and before the step of forming a nano-size insulation layer.
